(19) United States
(12) Patent Application Publication
(10) Pub. No.: US 2009/0021909 A1
(43) Pub. Date: Jan. 22, 2009

(54) METHOD AND SYSTEM FOR COOLING AT LEAST ON ELECTRONIC DEVICE

(75) Inventor: Ramprasad Soghal, Bangalore (IN)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONIC, N.V., EINDHOVEN (NL)

(21) Appl. No.: 10/597,254

(22) PCT Filed: Jan. 18, 2005
(86) PCT No.: PCT/IB05/50198

§ 371 Date: Jul. 18, 2006

(30) Foreign Application Priority Data
Jan. 22, 2004 (EP) 04100216.3

(51) Int. Cl. H05K 7/20; F24H 3/02

(52) U.S. Cl. 361/694; 165/85

(57) ABSTRACT

A method of cooling at least one electronic device is described, wherein a movable pumping element (4) pumps a fluid to and/or from said device, and wherein the movement of said pumping element (4) is induced by heat. A system for cooling at least one electronic device is described, comprising at least one movable pumping element (4) for transporting a fluid to and/or from said device, wherein said pumping element (4) is movable by heat.

### FIELD OF THE INVENTION

The invention relates to a method of cooling at least one electronic device.

The invention also relates to a system for cooling at least one electronic device.

### BACKGROUND OF THE INVENTION

A method and a system for cooling an electronic device are known from European patent application EP-A 1 020 911. In the known method and system, a case is mounted on a heat sink of an electronic device. A vibrating plate is located in the case for moving air through the case, such that the air cools the heat sink of the electronic device. The vibrating plate is driven by an electromagnet.

The known method has the drawback that it requires a relatively large amount of energy. Moreover, the heat, which is produced by the electronic device, is wasted. In the known method and system, the vibrating plate is set in motion by using an electromagnet. The resulting electromagnetic radiation may disturb the functioning of the electronic device. Moreover, the amount of cooling as provided by the known method is relatively low.

### OBJECT AND SUMMARY OF THE INVENTION

It is an object of the invention to provide an alternative method, particularly a better method, for cooling at least one electronic device. The invention aims at providing an efficient method of cooling at least one electronic device.

According to the present invention, this object is achieved by the features defined in claim 1.

According to the invention, a movable pumping element pumps a fluid to and/or from said electronic device, wherein the movement of said pumping element is induced by heat. The fluid can remove heat from said electronic device, with the result that the device is cooled. Since the movement of said pumping element is heat-induced, an efficient pumping of fluid can be achieved.

In a preferred embodiment of the method according to the invention, the heat for moving the pumping element at least comprises heat which is produced by said electronic device.

In that case, the electronic device can at least partially be involved in pumping said fluid. Particularly during use, the device produces heat, which heat is used in the movement of the pumping element for pumping said fluid to and/or from the device. Consequently, the heat produced by the electronic device is not wasted. For example, said fluid can simply transport the heat from the device to the pumping element. Besides, one or more separate heaters may be used to provide at least part of the heat for moving said pumping element. A heat pipe may also be used for transporting said heat.

It is also an object of the invention to provide an alternative system, particularly a better system, for cooling at least one electronic device. The invention aims at providing an efficient system for cooling at least one electronic device.

According to the invention, this object is achieved by the features defined in claim 12.

The system according to the invention comprises at least one movable pumping element for transporting a fluid, wherein said pumping element is movable by heat. Consequently, the system can operate relatively efficiently, using, for example, part of the heat which is produced by the device to be cooled. Besides, the movement of the pumping element may be achieved without any or substantially any electromagnetic radiation, which prevents disturbance of the operation of said electronic device due to such radiation.

The pumping element may be arranged, for example, to carry out a pumping movement under the influence of a heat-induced pressure rise. Besides, the pumping element may be arranged to carry out a pumping movement when the temperature of the pumping element changes. Such a temperature change can be brought about by said heat. To that end, the pumping element may contain and/or be coupled to a heat-sensitive material, a material having a high thermal coefficient of expansion, a bi-metal and/or the like.

According to a further aspect of the invention, an electronic device is provided with and/or coupled to a system as defined in any one of claims 12 to 31, wherein the electronic device is particularly a part of a computing means, a computer, a server and/or the like.

Said system can cool such an electronic device efficiently and preferably does not disturb its operation.

The invention further relates to an electronic product or apparatus, such as a magnetic tape or disc drive, an optical tape or disc drive, a TV-set, a monitor, a computer, a server or the like, the apparatus being provided with the system according to the invention.

Further advantageous embodiments of the invention are defined in the dependent claims. Various combinations of characteristic features defined in the claims are options.

The invention will now be described in more detail, by way of example, with reference to the embodiments shown in the accompanying drawings.

### BRIEF DESCRIPTION OF THE DRAWINGS

FIG. 1 is a schematic drawing of a first embodiment of the invention;

FIG. 2 is a schematic drawing of a second embodiment of the invention, wherein the pumping element is in a first position; and

FIG. 3 is a drawing similar to FIG. 2, wherein the pumping element is in a second position.

### DESCRIPTION OF EMBODIMENTS

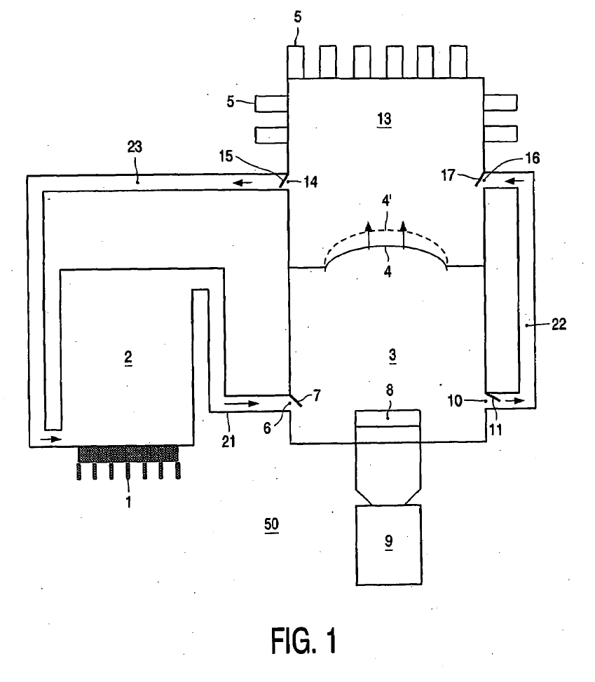

FIG. 1 shows a system for cooling an electronic device 1. The electronic device 1 may be, for example, a semiconductor device, a device comprising one or more amplification parts, a microelectronic device, an integrated circuit, a chip, a high current component, a resistor, and/or any other electronic or electric device which may heat up during operation. The system is a part of an electronic product 50.

The electronic device 1 is mounted on a heat collection chamber 2. The heat collection chamber 2 is filled with a suitable heat-transporting fluid comprising, for example, one or more liquids and/or gases. In an advantageous embodiment, the fluid is or comprises air, because air is cheap and safe in use. Alternatively, said fluid may comprise, for example, one or more refrigerants, for example, CFCs, HCFCs or similar refrigerating substances. The electronic device 1 is preferably mounted in such a way that the heat transfer coefficient between the device 1 and the fluid in the heat collection chamber 2 is relatively high. A heat sink, heat exchanger and/or a material having a high heat conductivity can be provided, for example, between the electronic device 1 and the content of the heat collection chamber 2. Besides, the electronic device can at least be partially located within the heat collection chamber 2.

During use, the electronic device 1 produces heat, which is at least partially collected by the fluid in the heat collection chamber 2. The fluid, as well as the heat contained therein, is removed from the heat collection chamber 2 via a discharge line 21 leading towards a pumping chamber 3, while the heat collection chamber 2 is replenished with fluid via a fluid supply line 23.

In the present embodiment, the fluid is pumped to and from the heat collection chamber 2 by a movable pumping element 4 in the form of a diaphragm. To this end, the diaphragm 4 forms a movable part of the wall of a fluid compression chamber 13 so that a first side of said diaphragm 4 abuts said compression chamber 13. The compression chamber 13 is provided with a fluid exhaust 14 comprising a first valve 15. The fluid exhaust 14 is connected to said heat collection chamber 2 via the supply line 23. Said first valve 15 is a one-way valve which allows fluid to flow from the compression chamber 13 into the supply line 23 via the exhaust 14. The compression chamber 13 further comprises a fluid inlet 16 which is provided with a second valve 17. Said second valve 17 is also a one-way valve which allows fluid to flow into the compression chamber 13 from a return line 22.

The compression chamber 13 is provided with cooling means 5 which are arranged to cool the content of the compression chamber 13. In the present embodiment, the cooling means of the compression chamber 13 comprise a heat exchanger which is provided with cooling ribs 5 extending in ambient air. Consequently, heat can be transferred from the content of the compression chamber 13 into its environment, resulting in cooling of the fluid. The inner walls of the compression chamber 13 preferably comprise a heat-absorbing material and/or coating to improve cooling of the content of the compression chamber 13.

Fluid flowing from the compression chamber 13 via the supply line 23 towards the heat collection chamber 2 is preferably additionally cooled, for example, by providing suitable expansion means. To this end, the exhaust valve 15 may be, for example, an expansion valve which is arranged to control the amount of fluid flowing through it, such that a fluid which is compressed in the compression chamber 13 is expanded and cooled in a controlled manner by the exhaust valve 15. Such an expansion valve may also be located downstream, in the supply line 23. The principles of such a cooling mechanism, using an expanding fluid, are known in the art.

During use, said fluid is supplied to the compression chamber 13 via said inlet 16. In the compression chamber, the fluid is cooled by using heat transfer via the cooling ribs 5. Besides, during use, the diaphragm 4 expands from a first to a second position, thereby compressing the fluid in the adjoining compression chamber 13. In FIG. 1, the first position of the diaphragm is represented by a solid line 4, whereas a broken line 4′ represents the second position. The compressed fluid can be further cooled by the cooling ribs 5. The expansion of said pumping diaphragm 4 also leads to pumping of said fluid. The compressed fluid flows from the compression chamber 13 via the exhaust 14 into the supply line 23. The compressed fluid is preferably expanded in and/or into the supply line 23, for example, by the first valve 15, leading to further cooling of said fluid. The resulting cooled fluid flows from the supply line 23 into the heat collection chamber 2, so that the fluid can provide cooling for the electronic device 1.

During compression of the fluid in the compression chamber 13, the second valve 17 is preferably closed, so that no compressed fluid can flow backwards into the return line 22. The second valve 17 can be arranged to close due to the rising pressure in the compression chamber 13. Besides, valve control means can be provided for controlling the second valve 17. To this end, the second valve 17 may be, for example, an electrically or electronically controllable valve.

Said valve control means may be, for example, suitable electronics, a microcontroller, a computer, mechanical means or the like. Besides, such valve control means may comprise one or more sensors to detect movement of the diaphragm and/or a pressure rise in the compression chamber 13. Said valve control means may also be arranged to cooperate with the pumping element 4 for a desired valve control. For example, said valve control means can be coupled mechanically, electrically, electronically or the like to the pumping element 4. Such valve control means are not shown in the Figures.

Furthermore, the first valve 15 is preferably opened substantially during and/or after compression of the fluid in the compression chamber 13 for allowing fluid to flow into the supply line 23 via the exhaust 14. The actions of the first valve 15 are preferably similar to the above-described actions of the second valve 17. For example, the first valve 15 may open due to the rise in pressure in the compression chamber and/or it may be controlled by suitable valve control means.

After the expansion of the diaphragm 4, the diaphragm 4 contracts back to the first position. Preferably at substantially the same time, the first valve 15 closes so that no fluid flows back from the supply line 23 into the compression chamber 13. Preferably at the same time, the second valve 17 opens so that a new amount of fluid can enter the compression chamber 13 via the fluid inlet 16. Also in this case, the movement of the first and/or the second valve may be pressure-induced, and/or such a movement may be brought about by valve control means.

The embodiment shown in FIG. 1 comprises a pumping chamber 3 for pumping the fluid from said device 1. In particular, the pumping chamber 3 is connected to the heat collection chamber 2 via the fluid discharge line 21. A third one-way valve 7 is provided in an exhaust 6 of the discharge line 21. This one-way valve 7 is arranged to allow fluid to flow from the collection chamber 2 into the pumping chamber 3.

Furthermore, said pumping chamber 3 can be brought in fluid connection with the compression chamber 13 by said fluid return line 22. To this end, an inlet 10 of the return line 22 comprises a fourth one-way valve 11 which is arranged to let fluid flow from the pumping chamber 3 towards the compression chamber 13.

According to the invention, the movement of said diaphragm 4 is heat-induced. In the present embodiment, the heat for moving the diaphragm 4 at least comprises heat which is produced by said electronic device 1. This is simply achieved by feeding fluid from the heat collection chamber 2 to the diaphragm 4. The system also comprises a separate heater 8 for providing part of the heat to move the diaphragm 4. Said heater 8 is arranged to heat the content of said pumping chamber 3. The heater 8 is controlled by a heater control and/or power supply 9. The heater 8 may comprise, for example, electric heating means, for example, one or more heating wires and/or resistances.

As is clearly shown, the diaphragm 4 separates said compression chamber 13 from said pumping chamber 3. The diaphragm 4 may be, for example, the wall or part of the wall that separates the compression chamber 13 from the pumping chamber 3. A second side of said pumping diaphragm 4 abuts the pumping chamber 3. The diaphragm 4 preferably comprises a heat-insulating material, so that substantially no or little heat can flow from the pumping chamber 3 to the compression chamber 13 via the diaphragm 4.

During use, the temperature as well as the pressure of the fluid in the collection chamber 2 rises. This is the result of building up heat, produced by the electronic device 1, in the collection chamber 2. Then, the third valve 7 is opened, for example, due to said pressure rise in the collection chamber 2 and/or by said valve control means. At about the same time, the fourth valve 11 is closed and/or is held in a closed position. The heated fluid then flows from the collection chamber 2 into the pumping chamber 3, resulting in a pressure rise in the pumping chamber 3.

The pressure in the pumping chamber 3 is preferably further raised by activation of the separate heater 8, whilst the third valve 7 is closed. In a preferred embodiment, the heater 8 generates a heat pulse to provide an instantaneous, short pressure pulse in the pumping chamber 3. During operation of the heater 8, both the third valve 7 and the fourth valve 11 are preferably closed. Because of the overall pressure rise in the pumping chamber 3, the diaphragm 4 is expanded from said first position to said second position, resulting in said compression of the content of the compression chamber 13, as has been described above.

After the heat-induced movement of the diaphragm 4 to the second position, the pressure in the compression chamber 1 decreases. This is achieved, inter alia, by allowing fluid to flow from the compression chamber 13 into the heat collection chamber 2 leading to said cooling of the electronic device 1, as has been described above.

Subsequently, at least the second valve 17 and the fourth valve 11 open or are opened, so that fluid can flow from the pumping chamber 3 into the compression chamber 13 via the return line 22. As a result, the pressure in the pumping chamber 3 decreases and the diaphragm 4 returns to its first position. At about the same time, said first valve 15 preferably closes or is closed, preventing an undesired return flow of fluid from the supply line 23 into the compression chamber 13. The pumping cycle can then be started all over again.

The system may comprise, for example, spring means for returning the diaphragm 4 from the second position to the first position. Such spring means may be, for example, separate means and/or the diaphragm may contain such means, particularly by using a resilient diaphragm 4. However, the movement of the diaphragm 4 between the first and the second position may be purely heat-induced, particularly due to heat-related pressure changes.

Because of the heat-induced movement of the diaphragm 4, the fluid is circulated between said at least one device 1 and said fluid cooling means 5. The fluid flows from the heat collection chamber 2 and the pumping chamber 3 into the compression chamber 13 and back to the heat collection chamber 2. Said diaphragm movement is preferably a pulsating or a vibrating movement, which can be achieved, for example, by applying heat pulses in the pumping chamber 3. Such a pulsating movement can also be achieved by providing appropriate valve control. Particularly the valves 15, 17, 7, 11 are preferably controlled with respect to each other in such a way that the fluid substantially only flows in the described direction between said chambers 2, 3, 13.

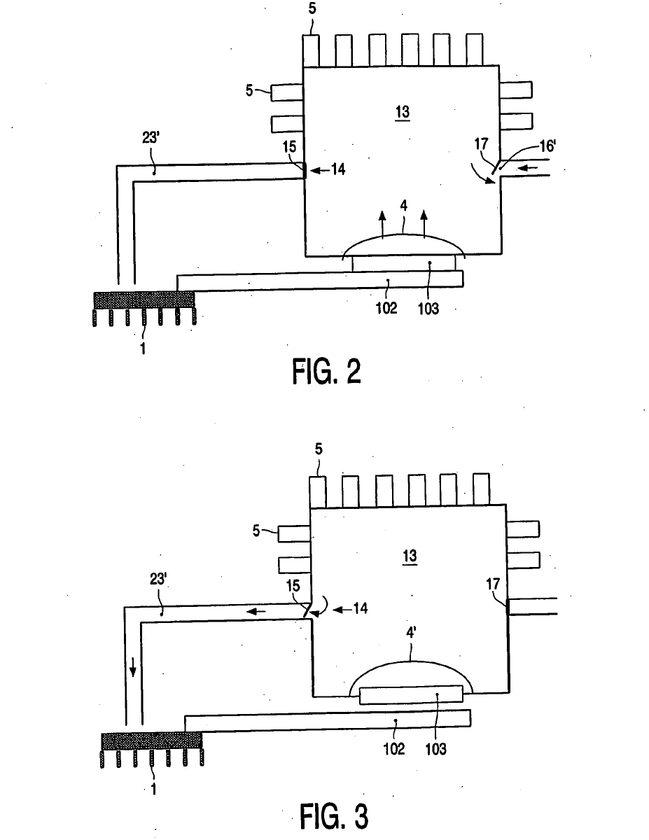

In the second embodiment, which is schematically shown in FIGS. 2 and 3, an electronic device 1 is attached to a heat collector 102. The heat collector 102 is formed as a heat pipe. The heat pipe 102 is arranged to transfer heat from the electronic device 1 to the pumping diaphragm 4, particularly by heat conduction, for heating the pumping diaphragm 4.

In the second embodiment, the pumping diaphragm 4 is arranged to carry out a pumping movement when its temperature changes. The pumping diaphragm 4 may contain and/or be coupled to, for example, one or more heat-sensitive materials, materials having high thermal coefficients of expansion, bi-metal and/or the like.

Similarly as in the first embodiment, a first side of the pumping diaphragm 4 of the second embodiment abuts a compression chamber 13. However, the second side of the pumping diaphragm 4 in the second embodiment extends opposite part of said heat pipe 102. In particular, the second side of the diaphragm 4 is provided with a heat-conducting plate 103 which touches the heat pipe 102 when the diaphragm 4 is in the first position, see FIG. 2. The diaphragm 4 is arranged to expand to the second position, shown in FIG. 3, due to a temperature rise of the diaphragm. In this second position, the heat-conducting plate 103 is moved away from the heat pipe 102.

The compression chamber 13 in the second embodiment is arranged substantially similarly as the compression chamber 13 in the first embodiment. In the second embodiment, a supply line 23′, which is connected to the compression chamber 13, extends towards the electronic device 1 so as to cool the device 1 with a cooling fluid. The supply line 23′ comprises a one-way valve 15, which is preferably an expansion valve for further cooling said cooling fluid. The compression chamber 13 comprises an inlet 16′ having a one-way valve 17 for replenishing the compression chamber 13 with fluid, for example, ambient air.

During use of the second embodiment, heat is generated by the electronic device 1. Part of the heat is absorbed by the heat pipe 102, so that its temperature rises. When the diaphragm 4 is in the first position, the heat pipe 102 also transfers part of the generated heat to the heat-conducting plate 103 of the diaphragm 4, resulting in a temperature rise of the diaphragm 4. The diaphragm 4 then expands or moves to its second position, shown in FIG. 3. Due to the expansion of the diaphragm 4, fluid is compressed in the compression chamber 13. The compressed fluid, which has been cooled by the cooling ribs 5 of the compression chamber 13 is then preferably expanded through an expansion valve 15, leading to further cooling of the fluid. The cooled fluid then flows via the supply line 23′ to the electronic device 1 for cooling the device 1.

The operation of the first valve 15 and the second valve 17 in the second embodiment may be similar to the operation of these valves in the first embodiment. These valves 15, 17 may be moved, for example, by pressure changes in the compression chamber 13 and/or by suitable valve control means. Such valve control means are preferably arranged to cooperate with the diaphragm 4, so that valve control is induced by diaphragm movements, and thus also by heat generated by the device.

After the expansion of the diaphragm 4, contact is lost between the heat pipe 102 and the heat-conducting plate 103 of the diaphragm 4. Consequently, the diaphragm 4 cools down, for example, by heat radiation, convection and/or conduction. Because of the decrease of temperature of the diaphragm 4, it returns from the second position to the first position, such that the heat-conducting plate 103 is again in contact with the heat pipe 102. The above-described pumping and cooling mechanism can then start all over again.

Alternatively, a further heater, which is not depicted, may be provided in the second embodiment for heating the diaphragm 4. Such a further heater may be desired, for example, when the flow of heat generated by the device 1 is not sufficient for moving the diaphragm to a desired second position.

The invention provides heat-induced pumping of a fluid to and/or from a device for cooling the device. Pumping is preferably automatic. Besides, the heat that is produced by the device may be advantageously used for driving the pumping means, particularly the movable pumping element 4 and preferably also the valve means, so that the pumping is energy-efficient.

Although the illustrative embodiments of the invention have been described in greater detail with reference to the accompanying drawings, it is to be understood that the invention is not limited to these embodiments. Various changes or modifications may be made by those skilled in the art without departing from the scope or spirit of the invention as defined in the claims.

The movable pumping element 4 may have different forms, shapes and sizes and may comprise various materials. It may comprise, for example, a membrane, a diaphragm or the like, or, for example, resilient and/or elastic materials, one or more metals, alloys, plastics, rubber or the like.

Furthermore, one or more movable pumping elements may be used for pumping said fluid, wherein the movement of at least one and preferably more of these elements is heat-induced.

The system may have different components in various forms and sizes, depending, inter alia, on the amount of cooling capacity which is desired, the available space for installing the system and similar considerations.

Furthermore, at least part of the system may be arranged to be mounted on or near an electronic device 1 for cooling this device.

1. A method of cooling at least one electronic device, wherein a movable pumping element (4) pumps a fluid to and/or from said electronic device, and wherein the movement of said pumping element (4) is induced by heat.

2. A method as claimed in claim 1, wherein said heat at least comprises heat which is produced by said electronic device.

3. A method as claimed in claim 1, wherein said heat is produced by at least one heater (8).

4. A method as claimed in claim 1, wherein the movement of said pumping element (4) is a pulsating and/or a vibrating movement.

5. A method as claimed in claim 1, wherein fluid is compressed by the movement of said pumping element (4), wherein the compressed fluid is cooled, and wherein the cooled fluid is transported to said at least one device.

6. A method as claimed in claim 1, wherein said pumping element circulates said fluid between said at least one device (1) and fluid cooling means (5).

7. A method as claimed in claim 1, wherein said fluid comprises air.

8. A method as claimed in claim 1, wherein said pumping element comprises a diaphragm (4).

9. A method as claimed in claim 5, wherein said fluid is supplied to a fluid compression chamber (13), wherein a first side of said diaphragm abuts said compression chamber (13), and wherein heat is supplied to a second side of said diaphragm (4) for moving the diaphragm into the compression chamber (13).

10. A method as claimed in claim 1, wherein said pumping element (4) is expanded from a first position to a second position by said heat, and wherein the expansion of said pumping element leads to pumping of said fluid.

11. A method as claimed in claim 10, wherein said heat is removed from the pumping element (4) after said expansion, such that the pumping element (4) contracts to said first position.

12. A system for cooling at least one electronic device, comprising at least one movable pumping element (4) for transporting a fluid to and/or from said device, wherein said pumping element (4) is movable by heat.

13. A system as claimed in claim 12, wherein said pumping element comprises a diaphragm (4), for example, an expandable and contractable diaphragm (4) which is movable between at least a first position and a second position.

14. A system as claimed in claim 12, comprising cooling means (5) for cooling said fluid.

15. A system as claimed in claim 14, wherein said cooling means comprise expansion means for expanding compressed fluid, for example, an expansion valve (15).

16. A system as claimed in claim 14, wherein said cooling means comprise a heat exchanger, particularly a cooling rib (5), for transporting heat from the fluid to the environment.

17. A system as claimed in claim 12, comprising a compression chamber (13) for compressing fluid, wherein a first side of said pumping element (4) abuts said compression chamber (13).

18. A system as claimed in claim 17, comprising a fluid supply (2, 23) for supplying fluid from said compression chamber (13) to said electronic device (1).

19. A system as claimed in claim 12, comprising a heat collector (2; 102) for collecting heat from said device.

20. A system as claimed in claim 19, wherein said heat collector comprises a heat pipe (102) which is connected or connectable to said pumping element (4) for supplying heat to the pumping element (4).

21. A system as claimed in claim 19, wherein said heat collector comprises a fluid which is at least contained in a heat collection chamber (2).

22. A system as claimed in claim 12, comprising a pumping chamber (3) for pumping fluid from said device, wherein a second side of said pumping element (4) abuts said pumping chamber (3).

23. A system as claimed in claim 21, wherein said pumping chamber (3) is fluid-connectable to said heat collection chamber (2).

24. A system as claimed in claim 17, wherein said pumping chamber (3) is fluid-connectable to said compression chamber (13), for example, by means of a fluid connection (22) which comprises a one-way valve (11, 17).

25. A system as claimed in claim 12, comprising at least one heater (8) for providing at least a part of the heat for moving said pumping element (4).

26. A system as claimed in claim 22, wherein said heater (8) is at least arranged to heat the content of said pumping chamber (3).

27. A system as claimed in claim 12, comprising valve means (15, 17, 7, 11) which are arranged to control the transport of said fluid.

28. A system as claimed in claim 27, wherein at least a part of said valve means is arranged to cooperate with said pumping element (4) for controlling the transport of said fluid, and wherein, for example, said cooperation is mechanical, electric, electronic or the like.

29. A system as claimed in claim 12, wherein at least a part of the system is arranged to be mounted on or near an electronic device for cooling said device.

30. A system as claimed in claim 12, wherein the pumping element (4) is arranged to carry out a pumping movement under the influence of a heat-induced pressure rise.

31. A system as claimed in claim 12, wherein the pumping element is arranged to carry out a pumping movement when the temperature of the pumping element changes.

32. An electronic device provided with and/or coupled to a system as claimed in claim 12, wherein the electronic device is particularly part of a computing means, a computer, a server and/or the like.

33. An apparatus provided with a system as claimed in claim 12.
